(19) United States
(12) Patent Application Publication
(10) Pub. No.: US 2025/0383419 A1
(43) Pub. Date: Dec. 18, 2025

(54) CALIBRATION OF INTEGRATED CURRENT SENSOR

(71) Applicant: Renesas Electronics America Inc., Milpitas, CA (US)

(72) Inventor: Marco SAUTTO, Zurich (CH)

(73) Assignee: Renesas Electronics America Inc., Milpitas, CA (US)

(21) Appl. No.: 19/237,272

(22) Filed: Jun. 13, 2025

Related U.S. Application Data
(60) Provisional application No. 63/659,610, filed on Jun. 13, 2024.

(51) Int. Cl. G01R 35/00; G01R 19/165

(52) U.S. Cl. CPC G01R 35/007; G01R 19/16576

(57) ABSTRACT

Systems and methods for implementing calibration of an integrated current sensor are described. A reference current can be applied to a sense resistor in a current sensing circuit. The reference current can be copied to generate a mirrored current. A magnitude of the reference current can be determined based on the mirrored current. A voltage drop across the sense resistor can be measured. A gain of the current sensing circuit can be determined based on the determined magnitude of the reference current and the measured voltage drop.

### CROSS-REFERENCE TO RELATED APPLICATION

The subject application claims the benefit of U.S. Provisional Application No. 63/659,610, filed on Jun. 13, 2024. The entire disclosure of U.S. Provisional Application No. 63/659,610 is incorporated by this reference.

### BACKGROUND

The present disclosure relates in general to semiconductor devices. More specifically, the present disclosure relates to calibration of integrated resistance.

Wireless power systems typically include power electronics such as inverters that generate alternating current (AC) waveforms, e.g., using pulse-width modulation (PWM) signals, to drive a transmission coil. To ensure efficient operation and safety, such systems commonly employ current sensing to monitor power flow, regulate inverter operation, and enable features such as foreign object detection (FOD), which identifies unintended conductive objects in the charging area.

### SUMMARY

In one embodiment, a method that can implement a calibration of an integrated current sensor is generally described. The method can include applying a reference current to a sense resistor in a current sensing circuit. The method can further include copying the reference current to generate a mirrored current. The method can further include determining a magnitude of the reference current based on the mirrored current. The method can further include measuring a voltage drop across the sense resistor. The method can further include determining a gain of the current sensing circuit based on the determined magnitude of the reference current and the measured voltage drop.

In one embodiment, a system that can implement a calibration of an integrated current sensor is generally described. The system can include a controller. The system can further include an integrated circuit. The integrated circuit can include a current sensing circuit including a sense resistor. The integrated circuit can further include a circuit configured to apply a reference current to the sense resistor in the current sensing circuit. The circuit can further copy the reference current to generate a mirrored current. The controller can determine a magnitude of the reference current based on the mirrored current. The controller can further measure a voltage drop across the sense resistor. The controller can further determine a gain of the current sensing circuit based on the determined magnitude of the reference current and the measured voltage drop.

In one embodiment, an integrated circuit that can implement a calibration of an integrated current sensor is generally described. The integrated circuit can include a current sensing circuit including a sense resistor. The integrated circuit can further include a circuit configured to apply a reference current to the sense resistor in the current sensing circuit. The circuit can further compare an output voltage of the current sensing circuit and a threshold voltage to generate a signal indicating a comparison result. The circuit can further, based on the signal, copy the reference current to generate a mirrored current. A magnitude of the reference current is based on the mirrored current. The current sensing circuit can output a voltage drop across the sense resistor in response to the application of the reference current to the sense resistor. A gain of the current sensing circuit is based on the determined magnitude of the reference current and the voltage drop.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1 is a diagram showing a system that can implement calibration of an integrated current sensor in one embodiment.

FIG. 2 is a diagram showing a system that can implement calibration of an integrated current sensor in another embodiment.

FIG. 3 is a flowchart of an example process that can implement calibration of an integrated current sensor in one embodiment.

### DETAILED DESCRIPTION

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

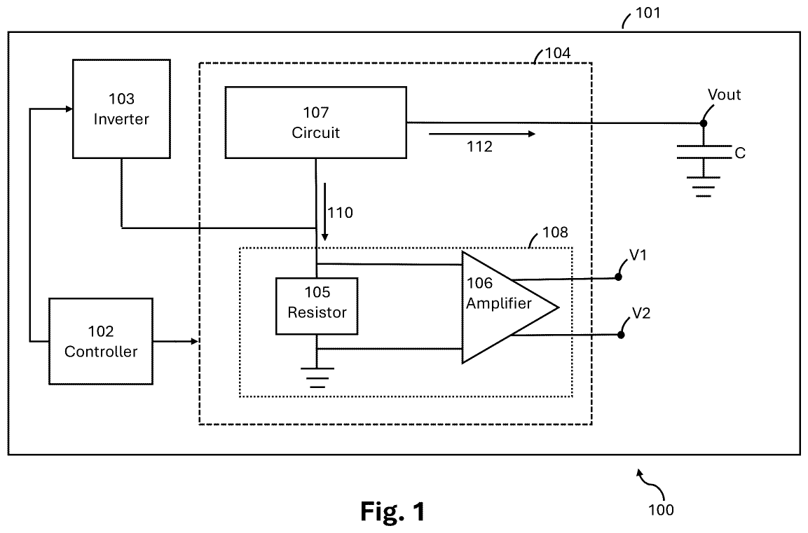

FIG. 1 is a diagram showing an example system that can implement calibration of integrated resistors. System 100 can include a power device 101. In one embodiment, power device 101 can operate as a wireless power transmitter and in another example embodiment, power device 101 can operate as a wireless power receiver. Power device 101 can include a controller 102.

Controller 102 can be configured to control and operate power device 101. Controller 102 can include, for example, a processor, central processing unit (CPU), field-programmable gate array (FPGA) or any other circuitry that is configured to control and operate power device 101. While described as a CPU in illustrative embodiments, controller 102 is not limited to a CPU in these embodiments and may comprise any other circuitry that is configured to control and operate power device 101 in system 100.

Power device 101 can further comprise a capacitor C, an inverter circuit 103, and an integrated circuit (IC) 104. Controller 102 can be configured to operate inverter circuit 103 during normal operation of power device 101 when functioning as a wireless power transmitter or receiver. Inverter circuit 103 can be configured to generate alternating current (AC) thereby generating an oscillating electromagnetic field for power device 101 to transmit a wireless signal. Further, the current generated by the inverter circuit 103 can be passed through a sense resistor, such as resistor 105, to be sensed.

Prior to the normal operation of inverter circuit 103, controller 102 can be configured to disable the inverter circuit 103 and enable IC 104 to perform calibration and/or sensing operations. IC 104 can include a resistor 105, amplifier 106, and a circuit 107. Resistor 105 and amplifier 106 can be configured to operate together as a current sensing circuit 108. Resistor 105 can be configured to be a sense resistor such that the current flowing through the path generates a voltage drop across the resistor 105. Resistor 105 can be a polysilicon resistor. Amplifier 106 can be connected in parallel to resistor 105. Amplifier 106 can be configured to sense the voltage drop across resistor 105 and output a differential voltage across nodes V1 and V2, where the voltage across nodes V1 and V2 corresponds to the current flowing through IC 104. This current sensing configuration may be used, for example, to regulate power delivery, monitor system operation, or detect abnormal conditions such as the presence of foreign objects. The current sensing circuit can sense the current generated by the inverter circuit 103 during normal operations and/or can sense other current passing through the resistor 105 prior to normal operations.

In conventional systems, current sensing can be implemented using a sense resistor and an integrated circuit (IC) including a voltage amplifier, without calibration components. In these conventional systems, the voltage amplifier can be integrated in the same IC while the sense resistor can be external to the IC. This arrangement allowed for the use of stable, well-characterized external sense resistors with known and significantly low temperature coefficients, but came at the cost of increased board space and the need for external routing and printed circuit board (PCB) layout complexity. In the systems described in the present disclosure, the sense resistor is also integrated within the IC alongside the amplifier, thereby improving system integration and reducing PCB component count. Further, to support accurate in-field calibration with the sense resistor being integrated in the IC, an external capacitor is introduced on the PCB. The capacitor can be of a relatively small size and provides high stability to replace the need for a bulkier discrete resistor. Also, calibration schemes are introduced in the present disclosure to address potential variations of the integrated sense resistors.

As shown in the embodiment of FIG. 1, IC 104 can be configured to integrate the resistor 105 while capacitor C is external to the IC 104. Further, IC 104 can include a circuit 107. Circuit 107 can be configured to calibrate the sensing behavior of resistor 105 and amplifier 106 by determining a transimpedance (current-to-voltage) gain Gᵢᵥ of the current sensing circuit 108.

In one embodiment, circuit 107 can be activated prior to normal operation of inverter circuit 103 to initiate a calibration procedure. During this calibration, circuit 107 can be configured to generate a reference current 110 and apply reference current 110 to the current sensing circuit 108. In one embodiment, reference current 110 can be applied to resistor 105 to generate a voltage drop across resistor 105. At the same time, circuit 107 can output a mirrored version of the reference current 110, labeled as a mirrored current 112, that can be applied to capacitor C to generate Vout. In one embodiment, reference current 110 can be a direct current (DC) signal and mirrored current 112 can be an alternating current (AC) signal generated by mirroring reference current 110 and alternating the direction. Controller 102 can control threshold voltages being used internally by circuit 107 to generate Vout that varies according to a triangular waveform, such that capacitor C can be charged and discharged alternately. Since controller 102 controls the threshold voltages being used in circuit 107, reference current 110 or mirrored current 112 can be known to controller 102 and controller 102 can determine a current-to-voltage gain, or a transimpedance gain Gᵢᵥ based on the known reference current 110 and the voltage drop outputted from amplifier 106. The transimpedance gain Gᵢᵥ can be indicative of whether the output of amplifier 106 is deviating from reference current 110, where such deviation can be indicative of a performance of resistor 105. Controller 102 can use transimpedance gain Gᵢᵥ to compensate for drift in resistor 105 or amplifier 106 due to temperature, manufacturing variation, or long-term aging.

In some embodiments, current sensing circuit 108 may include the integrated resistor 105 and amplifier 106 pair as described above, while in other embodiments current sensing circuit 108 may utilize alternate sensing elements such as Hall effect sensors, current mirrors, or magnetic sensors. Accordingly, the calibration implementation is not limited to resistor-based current sensing and may be applied to any system in which current sensing gain calibration is desired. Although described in the context of a wireless power transmitter or receiver, the system 100 is applicable to a broad range of current sensing systems in which calibration accuracy and aging compensation are needed.

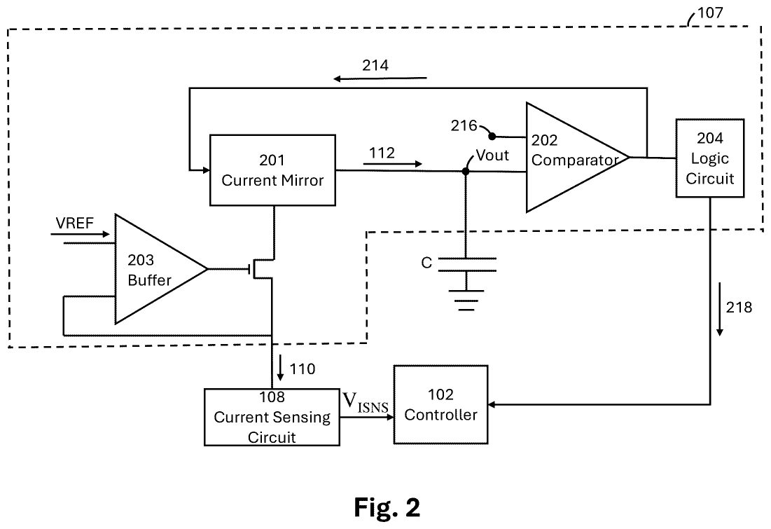

FIG. 2 is a diagram showing an implementation of calibration of integrated resistors. Descriptions of FIG. 2 may reference components shown in FIG. 1. In the example embodiment shown in FIG. 2, circuit 107 can comprise of a current mirror 201, comparator 202, buffer 203 and logic circuit 204. Buffer 203 can be an amplifier configured to receive a reference voltage VREF. Based on the reference voltage VREF, the buffer 203 can generate the reference current 110 to be provided to current sensing circuit 108. Current mirror 201 is a circuit configured to copy the reference current 110. Current mirror 201 can comprise of at least two identical transistors, for example Bipolar Junction Transistors (BJTs) or Metal-Oxide Semiconductor Field Effect Transistors (MOSFETs). Current mirror 201 can be configured to replicate the reference current 110 flowing through resistor 105 in current sensing circuit 108. The replicated current can be output from current mirror 201 as mirror current 112. Current mirror 201 is configured to output mirror current 112 as a positive current or a negative current. When mirror current 112 is output to node Vout as a positive current, capacitor C can be charged up. When mirror current 112 is output to node Vout as a negative current, capacitor C can be discharged.

Comparator 202 can be configured to compare Vout to a reference threshold voltage 216. Threshold voltage 216 can correspond to either one of an upper threshold voltage (e.g., 2V, 1.4V, or other voltage levels) or a lower threshold voltage (e.g., 1V, 0.4V, or other voltage levels). The upper threshold voltage can be an upper bound of threshold voltage 216, and can define the peak value of Vout. The lower threshold voltage can be a lower bound of threshold voltage 216, and can define the valley value of Vout. Threshold voltage 216 can be set or toggled, such as by controller 102, between the upper threshold and the lower threshold alternately. Comparator 202 can be configured to compare Vout with threshold voltage 216 and output a switching signal 214 based on the comparison. Switching signal 214 can indicate whether Vout reached threshold voltage 216 or exceed threshold voltage 216. Switching signal 214 can trigger current mirror 201 to generate mirrored current 112 as either a positive mirrored current or a negative mirrored current. Mirrored current 112 can be applied to capacitor C, causing the capacitor voltage to increase or decrease depending on the direction of the current. When mirrored current 112 is a positive current, Vout can increase to charge capacitor C. When mirrored current 112 is a negative current, Vout can decrease to discharge capacitor C. Controller 102 can toggle threshold voltage 216 alternately between the upper threshold voltage and the lower threshold voltage to switch the polarity of mirrored current 112. As mirrored current 112 switches between positive current and negative current, Vout varies according to a triangular waveform that varies linearly between the peak value defined by the upper threshold voltage and the valley value defined by the lower threshold voltage.

In one embodiment, when Vout is decreasing, capacitor C is being discharged, current mirror 201 is outputting mirror current 112 as a negative current and controller 102 can set threshold voltage 216 to the lower threshold voltage. When Vout decreases to threshold voltage 216, or exceed to lower than threshold voltage 216, comparator 202 can output switching signal 214 as a logic low signal (or voltage representing logic low) to current mirror 201. Current mirror 201 can receive switching signal 214 that is logic low and, in response, changes a polarity of Vout by outputting a positive current. In some embodiments, switching signal 214 can be provided to controller 102 to trigger controller 102 to change threshold voltage 216 from the lower threshold voltage to the upper threshold voltage. The positive current being outputted by current mirror 201 can cause Vout to increase (it was originally decreasing) and begin charging capacitor C.

In one embodiment, when Vout is increasing, capacitor C is being charged, current mirror 201 is outputting mirror current 112 as positive current and controller 102 can set threshold voltage 216 to the upper threshold voltage. When Vout increases to threshold voltage 216, or exceed to greater than threshold voltage 216, comparator 202 can output switching signal 214 as a logic high signal (or voltage representing logic high) to current mirror 201. Current mirror 201 can receive switching signal 214 that is logic high and, in response, changes a polarity of Vout by outputting a negative current. In some embodiments, switching signal 214 can be provided to controller 102 to trigger controller 102 to change threshold voltage 216 from the upper threshold voltage to the lower threshold voltage. The negative current being outputted by current mirror 201 can cause Vout to decrease (it was originally increasing) and begin discharging capacitor C. The alternate output of mirrored current 112 as positive current and negative current can cause Vout to have a triangular waveform. The control of threshold voltage 216 based on switching signal 214 can provide precise timing to change polarity of Vout.

In one embodiment, logic circuit 204 can be an integer divider configured to divide a signal by a known amount. Logic circuit 204 can be implemented by digital logic components, such as flip-flops. Comparator 202 can output switching signal 214 to logic circuit 204 and logic circuit 204 can divide switching signal 214 by a known amount to generate a digital signal 218. Digital signal 218 can have a frequency equal to half the frequency at which the threshold voltage 216 being inputted to comparator 202 is being toggled. Digital signal 218 can be outputted to controller 102 and controller 102 can measure a frequency fₒᵤₜ of the digital signal 218, which can also be a frequency of the triangular waveform of Vout, to determine the magnitude of the reference current 110 flowing through resistor 105.

The current-to-frequency gain G_{if} of circuit 107 is a predefined constant that can be stored in a memory device of controller 102. Given that gain G_{if} is predefined and the frequency fₒᵤₜ is determined by the controller 102, the magnitude of the reference current 110 can be determined using the following relationship:

$$\frac{{f}_{out}}{{G}_{if}} = {I}_{force} ,$$

wherein I_{force} is the magnitude of the reference current 110. In an aspect, the value of I_{force} may not be need to be a stable or repeatable value, the absolute magnitude will be reconstructed based on the output frequency fₒᵤₜ of the output voltage Vout, hence internal current sources to the IC 104, may not be needed to provide high accuracy, their implementation can be relatively simple. As explained above with respect to FIG. 1, amplifier 106 can be configured to output a differential voltage signal across a pair of nodes V1 and V2, where the voltage between V1 and V2 corresponds to the voltage drop across resistor 105 caused by reference current 110. In one example, an analog-to-digital converter (ADC) can be connected to nodes V1 and V2 to sample and digitize the voltage across the nodes V1 and V2 as a digital voltage signal V_{ISNS}. In some example embodiments, the ADC can be integrated within the IC 104 and in some example embodiments, the ADC can be external to IC 104. Controller 102 can be configured to receive the digitized voltage V_{ISNS} from the ADC. Using the digitized voltage V_{ISNS} and the calculated reference current 110, controller 102 can be configured to determine the transimpedance gain Gᵢᵥ associated with the current sensing path formed by resistor 105 and amplifier 106. The transimpedance gain Gᵢᵥ can be determined according to the following relationship:

$$\frac{{V}_{ISNS}}{{I}_{force}} = {G}_{iv} .$$

The determined transimpedance gain Gᵢᵥ can represent the actual gain of the sensing path at the time of calibration. Controller 102 can be configured to use the determined transimpedance gain Gᵢᵥ to calibrate the current sensing path and to compensate for variation in resistor 105 caused by manufacturing tolerance, temperature variation, or long-term aging.

In order for the controller 102 to determine the reference current 110 while circuit 107 is enabled, the current-to-frequency gain G_{if} of circuit 107 must be known. As such, G_{if} is determined and stored during a calibration step during manufacturing, e.g., post-surface-mount assembly (post-SMT), to determine the magnitude of the reference current 110 and to calibrate the current sensing circuit 108.

As part of the calibration process, the current-to-voltage gain of the amplifier 106 as a function of temperature, Gᵢᵥ(T), can first be determined using a precision current generator. The precision current generator can be used to apply known values of current to resistor 105 while amplifier 106 outputs the corresponding differential voltage signal V_{ISNS}. Using the applied current and the measured voltage, the gain Gᵢᵥ(T) can be determined and stored. Once gain Gᵢᵥ(T) has been calibrated, circuit 107 can be enabled and the generated reference current 110, i.e., I_{force}, can be used to generate signal Vout, a triangular waveform, and corresponding digital signal 218. The frequency of the digital signal 218, referred to as fₒᵤₜ, can be measured by controller 102. By providing different reference voltage VREF values, different I_{force} values can be generated. Thereby, applying two distinct I_{force} values at two different temperature points, for example 50 mA and 100 mA at 25° C. and 100° C., and by measuring the resulting changes in V_{ISNS} and fₒᵤₜ, the current-to-frequency gain G_{if}(T) can be calculated and stored using the same relationships described above. G_{if}(T) can then be used during in-field operation to determine the magnitude of I_{force} based on measured fₒᵤₜ, enabling controller 102 to update or recalibrate Gᵢᵥ(T) as needed.

In another example, the calibration process can be performed under the assumption that the temperature remains constant during calibration. In this case, the temperature-dependent gain Gᵢᵥ(T) can be treated as a temperature-invariant gain Gᵢᵥ. The precision current generator can again apply known current values to resistor 105, and amplifier 106 can generate corresponding differential voltage signals V_{ISNS}. Once Gᵢᵥ is calculated and stored, circuit 107 can be enabled to generate signal Vout and corresponding digital signal 218 using the generated I_{force} current. By applying two or more distinct I_{force} current values and measuring the resulting fₒᵤₜ and V_{ISNS} values, the current-to-frequency gain G_{if} can be calculated and stored. Considering the G_{if} independent from temperature, the stored G_{if} can then be used during in-field operation to determine I_{force} from measured fₒᵤₜ, allowing controller 102 to recalculate or refine Gᵢᵥ as needed, without accounting for temperature variation.

The value of G_{if} can be treated as constant over time and temperature due to circuit design and component selection. For example, circuit 107 may be powered off during normal operation, thereby reducing long-term drift. Chopping techniques may be applied to further reduce the drift due to aging. In addition, capacitor C may be selected as a COG or oxide capacitor, both of which are known to exhibit stable capacitance over time and temperature.

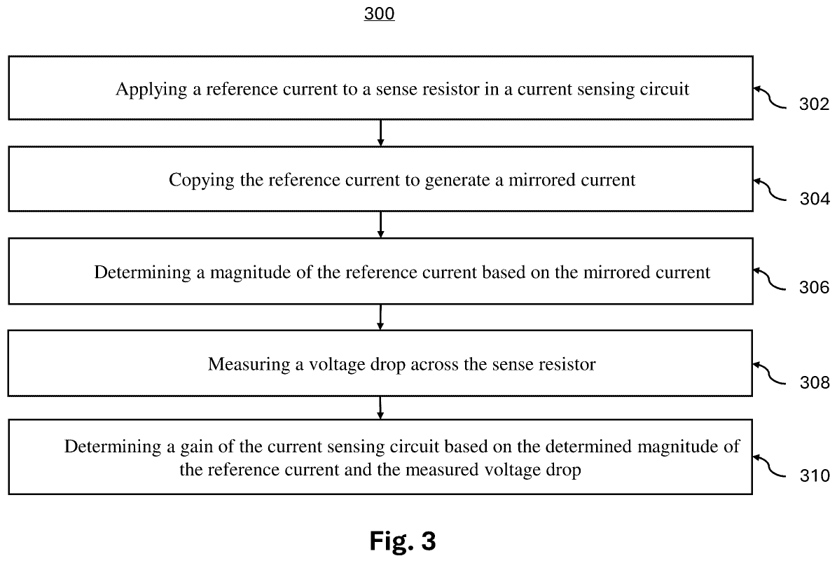

FIG. 3 is a flowchart of an example process that can implement calibration of integrated resistance in one embodiment. Descriptions of FIG. 3 may reference components shown in FIGS. 1-2. The process 300 can include one or more operations, actions, or functions as illustrated by one or more of blocks 302, 304, 306, 308, and 310. Although illustrated as discrete blocks, various blocks can be divided into additional blocks, combined into fewer blocks, eliminated, performed in different order, or performed in parallel, depending on the desired implementation.

Process 300 can be performed by a wireless power system, i.e., system 100. Process 300 can begin a block 302, where the system can apply a reference current to a sense resistor in a current sensing circuit. The process can continue from block 302 to block 304. At block 304, the system can copy the reference current to generate a mirrored current. The process can continue from block 304 to block 306. At block 306, the system can determine a magnitude of the reference current based on the mirrored current. The process can continue block 306 to block 308. At block 308, the system can measure a voltage drop across the sense resistor. The process can continue from block 308 to block 310. At block 310, the system can determine a gain of the current sensing circuit based on the determined magnitude of the reference current and the measured voltage drop.

In another embodiment, copying the reference current to generate the mirrored current comprises comparing an output voltage of the current sensing circuit and a threshold voltage to generate a signal indicating a comparison result. Based on the signal, the system can copy the reference current to generate the mirrored current as one of a positive current and a negative current.

In another embodiment, when the signal indicates the output voltage of the current sensing circuit reaches an upper bound of the threshold voltage, the system can copy the reference current to generate the mirrored current as the negative current. When the signal indicates the output voltage of the current sensing circuit reaches a lower bound of the threshold voltage, the system can copy the reference current to generate the mirrored current as the positive current. The output voltage of the current sensing circuit is bounded by the upper bound and the lower bound of the threshold voltage.

In another embodiment, the output voltage of the current sensing circuit reaches the upper bound of the threshold voltage when the output voltage of the current sensing circuit is increasing to charge a capacitor external to the current sensing circuit. The output voltage of the current sensing circuit reaches the lower bound of the threshold voltage when the output voltage of the current sensing circuit is decreasing to discharge the capacitor external to the current sensing circuit.

In another embodiment, when the signal indicates the output voltage of the current sensing circuit reaches an upper bound of the threshold voltage, the system can set the threshold voltage to the lower bound. When the signal indicates the output voltage of the current sensing circuit reaches a lower bound of the threshold voltage, the system can set the threshold voltage to the upper bound.

In another embodiment, determining the magnitude of the reference current based on the mirrored current comprises the system to determine a frequency of an output voltage that is based on the mirrored current. The system can divide the frequency of the output voltage by a predefined current-to-frequency gain associated with the current sensing circuit to determine the magnitude of the reference current.

In another embodiment, determining the frequency of the output voltage comprises the system to compare the output voltage and a threshold voltage to generate a signal indicating a comparison result. The system can divide the signal by a predefined value to generate another signal. The system can measure a frequency of said another signal, the measured frequency is the frequency of the output voltage.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

### EXAMPLES

Example 1: A method comprising: applying a reference current to a sense resistor in a current sensing circuit; copying the reference current to generate a mirrored current; determining a magnitude of the reference current based on the mirrored current; measuring a voltage drop across the sense resistor; and determining a gain of the current sensing circuit based on the determined magnitude of the reference current and the measured voltage drop.

Example 2: A method of example 1, wherein copying the reference current to generate the mirrored current comprises: comparing an output voltage of the current sensing circuit and a threshold voltage to generate a signal indicating a comparison result; and based on the signal, copying the reference current to generate the mirrored current as one of a positive current and a negative current.

Example 3: The method of any one of examples 1 to 2, further comprising: when the signal indicates the output voltage of the current sensing circuit reaches an upper bound of the threshold voltage, copying the reference current to generate the mirrored current as the negative current; and when the signal indicates the output voltage of the current sensing circuit reaches a lower bound of the threshold voltage, copying the reference current to generate the mirrored current as the positive current, wherein the output voltage of the current sensing circuit is bounded by the upper bound and the lower bound of the threshold voltage.

Example 4: The method of any one of examples 1 to 3, wherein: the output voltage of the current sensing circuit reaches the upper bound of the threshold voltage when the output voltage of the current sensing circuit is increasing to charge a capacitor external to the current sensing circuit; and the output voltage of the current sensing circuit reaches the lower bound of the threshold voltage when the output voltage of the current sensing circuit is decreasing to discharge the capacitor external to the current sensing circuit.

Example 5: The method of any one of examples 1 to 4, further comprising: when the signal indicates the output voltage of the current sensing circuit reaches an upper bound of the threshold voltage, setting the threshold voltage to the lower bound; and when the signal indicates the output voltage of the current sensing circuit reaches a lower bound of the threshold voltage, setting the threshold voltage to the upper bound.

Example 6: The method of any one of examples 1 to 5, wherein determining the magnitude of the reference current based on the mirrored current comprises: determining a frequency of an output voltage that is based on the mirrored current; and dividing the frequency of the output voltage by a predefined current-to-frequency gain associated with the current sensing circuit to determine the magnitude of the reference current.

Example 7: The method of any one of examples 1 to 6, wherein determining the determining the frequency of the output voltage comprises: comparing the output voltage and a threshold voltage to generate a signal indicating a comparison result; dividing the signal by a predefined value to generate another signal; and measuring a frequency of said another signal, wherein the measured frequency is the frequency of the output voltage.

Example 8: A system comprising: a controller; an integrated circuit comprising: a current sensing circuit including a sense resistor; a circuit configured to: apply a reference current to the sense resistor in the current sensing circuit; copy the reference current to generate a mirrored current; the controller being configured to: determine a magnitude of the reference current based on the mirrored current; measure a voltage drop across the sense resistor; and determine a gain of the current sensing circuit based on the determined magnitude of the reference current and the measured voltage drop.

Example 9. The system of example 8, wherein the circuit is further configured to: compare an output voltage of the current sensing circuit and a threshold voltage to generate a signal indicating a comparison result; and based on the signal, copy the reference current to generate the mirrored current as one of a positive current and a negative current.

Example 10: The system of any one of examples 8 to 9, wherein the circuit is further configured to: when the signal indicates the output voltage of the current sensing circuit reaches an upper bound of the threshold voltage, copy the reference current to generate the mirrored current as the negative current; and when the signal indicates the output voltage of the current sensing circuit reaches a lower bound of the threshold voltage, copy the reference current to generate the mirrored current as the positive current, wherein the output voltage of the current sensing circuit is bounded by the upper bound and the lower bound of the threshold voltage.

Example 11: The system of any one of examples 8 to 10, wherein: the output voltage of the current sensing circuit reaches the upper bound of the threshold voltage when the output voltage of the current sensing circuit is increasing to charge a capacitor external to the current sensing circuit; and the output voltage of the current sensing circuit reaches the lower bound of the threshold voltage when the output voltage of the current sensing circuit is decreasing to discharge the capacitor external to the current sensing circuit.

Example 12: The system of any one of examples 8 to 11, wherein the controller is further configured to: when the signal indicates the output voltage of the current sensing circuit reaches an upper bound of the threshold voltage, set the threshold voltage to the lower bound; and when the signal indicates the output voltage of the current sensing circuit reaches a lower bound of the threshold voltage, set the threshold voltage to the upper bound.

Example 13: The system of any one of examples 8 to 12, wherein the controller is further configured to: determine a frequency of an output voltage that is based on the mirrored current; and divide the frequency of the output voltage by a predefined current-to-frequency gain associated with the current sensing circuit to determine the magnitude of the reference current.

Example 14: The system of any one of examples 8 to 13, wherein the controller is further configured to: compare the output voltage and a threshold voltage to generate a signal indicating a comparison result; divide the signal by a predefined value to generate another signal; and measure a frequency of said another signal, wherein the measured frequency is the frequency of the output voltage.

Example 15: An integrated circuit comprising: a current sensing circuit including a sense resistor; a circuit configured to: apply a reference current to the sense resistor in the current sensing circuit; compare an output voltage of the current sensing circuit and a threshold voltage to generate a signal indicating a comparison result; and based on the signal, copy the reference current to generate a mirrored current, wherein a magnitude of the reference current is based on the mirrored current; and the current sensing circuit being configured to output a voltage drop across the sense resistor in response to the application of the reference current to the sense resistor, wherein a gain of the current sensing circuit is based on the determined magnitude of the reference current and the voltage drop.

Example 16. The integrated circuit of example 15, wherein the circuit is further configured to: based on the signal, copy the reference current to generate the mirrored current as one of a positive current and a negative current.

Example 17: The integrated circuit of any one of examples 15 to 16, wherein the circuit is further configured to: when the signal indicates the output voltage of the current sensing circuit reaches an upper bound of the threshold voltage, copy the reference current to generate the mirrored current as a negative current; and when the signal indicates the output voltage of the current sensing circuit reaches a lower bound of the threshold voltage, copy the reference current to generate the mirrored current as a positive current, wherein the output voltage of the current sensing circuit is bounded by the upper bound and the lower bound of the threshold voltage.

Example 18: The integrated circuit of any one of examples 15 to 17, wherein: the output voltage of the current sensing circuit reaches the upper bound of the threshold voltage when the output voltage of the current sensing circuit is increasing to charge a capacitor external to the current sensing circuit; and the output voltage of the current sensing circuit reaches the lower bound of the threshold voltage when the output voltage of the current sensing circuit is decreasing to discharge the capacitor external to the current sensing circuit.

Example 19: The integrated circuit of any one of examples 15 to 18, wherein: when the signal indicates the output voltage of the current sensing circuit reaches an upper bound of the threshold voltage, the threshold voltage is set to the lower bound; and when the signal indicates the output voltage of the current sensing circuit reaches a lower bound of the threshold voltage, the threshold voltage is set to the upper bound.

Example 20: The integrated circuit of any one of examples 15 to 19, wherein the magnitude of the reference current is based on a frequency of the output voltage.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A method comprising:
applying a reference current to a sense resistor in a current sensing circuit;
copying the reference current to generate a mirrored current;
determining a magnitude of the reference current based on the mirrored current;
measuring a voltage drop across the sense resistor; and
determining a gain of the current sensing circuit based on the determined magnitude of the reference current and the measured voltage drop.

2. The method of claim 1, wherein copying the reference current to generate the mirrored current comprises:
comparing an output voltage of the current sensing circuit and a threshold voltage to generate a signal indicating a comparison result; and
based on the signal, copying the reference current to generate the mirrored current as one of a positive current and a negative current.

3. The method of claim 2, further comprising:
when the signal indicates the output voltage of the current sensing circuit reaches an upper bound of the threshold voltage, copying the reference current to generate the mirrored current as the negative current; and
when the signal indicates the output voltage of the current sensing circuit reaches a lower bound of the threshold voltage, copying the reference current to generate the mirrored current as the positive current,
wherein the output voltage of the current sensing circuit is bounded by the upper bound and the lower bound of the threshold voltage.

4. The method of claim 3, wherein:
voltage when the output voltage of the current sensing circuit is increasing to charge a capacitor external to the current sensing circuit; and
the output voltage of the current sensing circuit reaches the lower bound of the threshold voltage when the output voltage of the current sensing circuit is decreasing to discharge the capacitor external to the current sensing circuit.

5. The method of claim 2, further comprising:
when the signal indicates the output voltage of the current sensing circuit reaches an upper bound of the threshold voltage, setting the threshold voltage to the lower bound; and
when the signal indicates the output voltage of the current sensing circuit reaches a lower bound of the threshold voltage, setting the threshold voltage to the upper bound.

6. The method of claim 1, wherein determining the magnitude of the reference current based on the mirrored current comprises:
determining a frequency of an output voltage that is based on the mirrored current; and
dividing the frequency of the output voltage by a predefined current-to-frequency gain associated with the current sensing circuit to determine the magnitude of the reference current.

7. The method of claim 6, wherein determining the determining the frequency of the output voltage comprises:
comparing the output voltage and a threshold voltage to generate a signal indicating a comparison result;
dividing the signal by a predefined value to generate another signal; and
measuring a frequency of said another signal, wherein the measured frequency is the frequency of the output voltage.

8. A system comprising:
a controller; and
an integrated circuit comprising:
a current sensing circuit including a sense resistor; and
a circuit configured to:
apply a reference current to the sense resistor in the current sensing circuit; and
copy the reference current to generate a mirrored current;
the controller being configured to:
determine a magnitude of the reference current based on the mirrored current;
measure a voltage drop across the sense resistor; and
determine a gain of the current sensing circuit based on the determined magnitude of the reference current and the measured voltage drop.

9. The system of claim 8, wherein the circuit is further configured to:
compare an output voltage of the current sensing circuit and a threshold voltage to generate a signal indicating a comparison result; and
based on the signal, copy the reference current to generate the mirrored current as one of a positive current and a negative current.

10. The system of claim 9, wherein the circuit is further configured to:
when the signal indicates the output voltage of the current sensing circuit reaches an upper bound of the threshold voltage, copy the reference current to generate the mirrored current as the negative current; and
when the signal indicates the output voltage of the current sensing circuit reaches a lower bound of the threshold voltage, copy the reference current to generate the mirrored current as the positive current,
wherein the output voltage of the current sensing circuit is bounded by the upper bound and the lower bound of the threshold voltage.

11. The system of claim 10, wherein:
voltage when the output voltage of the current sensing circuit is increasing to charge a capacitor external to the current sensing circuit; and
the output voltage of the current sensing circuit reaches the lower bound of the threshold voltage when the output voltage of the current sensing circuit is decreasing to discharge the capacitor external to the current sensing circuit.

12. The system of claim 9, wherein the controller is further configured to:
when the signal indicates the output voltage of the current sensing circuit reaches an upper bound of the threshold voltage, set the threshold voltage to the lower bound; and
when the signal indicates the output voltage of the current sensing circuit reaches a lower bound of the threshold voltage, set the threshold voltage to the upper bound.

13. The system of claim 8, wherein the controller is further configured to:
determine a frequency of an output voltage that is based on the mirrored current; and
divide the frequency of the output voltage by a predefined current-to-frequency gain associated with the current sensing circuit to determine the magnitude of the reference current.

14. The system of claim 13, wherein the controller is further configured to:
compare the output voltage and a threshold voltage to generate a signal indicating a comparison result;
divide the signal by a predefined value to generate another signal; and
measure a frequency of said another signal, wherein the measured frequency is the frequency of the output voltage.

15. An integrated circuit comprising:
a current sensing circuit including a sense resistor; and
a circuit configured to:
apply a reference current to the sense resistor in the current sensing circuit;
compare an output voltage of the current sensing circuit and a threshold voltage to generate a signal indicating a comparison result; and
based on the signal, copy the reference current to generate a mirrored current, wherein a magnitude of the reference current is based on the mirrored current,
the current sensing circuit being configured to output a voltage drop across the sense resistor in response to the application of the reference current to the sense resistor, wherein a gain of the current sensing circuit is based on the determined magnitude of the reference current and the voltage drop.

16. The integrated circuit of claim 15, wherein the circuit is further configured to:
based on the signal, copy the reference current to generate the mirrored current as one of a positive current and a negative current.

17. The integrated circuit of claim 15, wherein the circuit is further configured to:
when the signal indicates the output voltage of the current sensing circuit reaches an upper bound of the threshold voltage, copy the reference current to generate the mirrored current as a negative current; and
when the signal indicates the output voltage of the current sensing circuit reaches a lower bound of the threshold voltage, copy the reference current to generate the mirrored current as a positive current,
wherein the output voltage of the current sensing circuit is bounded by the upper bound and the lower bound of the threshold voltage.

18. The integrated circuit of claim 17, wherein:
the output voltage of the current sensing circuit reaches the upper bound of the threshold voltage when the output voltage of the current sensing circuit is increasing to charge a capacitor external to the current sensing circuit; and
the output voltage of the current sensing circuit reaches the lower bound of the threshold voltage when the output voltage of the current sensing circuit is decreasing to discharge the capacitor external to the current sensing circuit.

19. The integrated circuit of claim 15, wherein:
when the signal indicates the output voltage of the current sensing circuit reaches an upper bound of the threshold voltage, the threshold voltage is set to the lower bound; and
when the signal indicates the output voltage of the current sensing circuit reaches a lower bound of the threshold voltage, the threshold voltage is set to the upper bound.

20. The integrated circuit of claim 15, wherein the magnitude of the reference current is based on a frequency of the output voltage.
